(19) United States
(12) Patent Application Publication
(10) Pub. No.: US 2017/0059680 A1
(43) Pub. Date: Mar. 2, 2017

(54) FAST SPIN MAGNETIC RESONANCE IMAGING METHOD AND SYSTEM

(71) Applicant: General Electric Company, Schenectady, NY (US)

(72) Inventors: YUVAL ZUR, HAIFA (IL); WEITIAN CHEN, CONCORD, CA (US)

(73) Assignee: GENERAL ELECTRIC COMPANY, SCHENECTADY, NY (US)

(21) Appl. No.: 14/840,872

(22) Filed: Aug. 31, 2015

(51) Int. Cl. G01R 33/561; G01R 33/36; G01R 33/54; G01R 33/48; G01R 33/385; G01R 33/34

(52) U.S. Cl. CPC G01R 33/5611; G01R 33/3852; G01R 33/34; G01R 33/543; G01R 33/4818; G01R 33/3614

(57) ABSTRACT

A 3D parallel imaging method includes the steps of acquiring a partial CPMG data set, acquiring a partial CP data set, and interleaving the partial CPMG data set and the partial CP data set at different ky-kz locations.

### BACKGROUND

Technical Field

Embodiments of the invention relate generally to magnetic resonance imaging and, more specifically, to a system and method of stable parallel imaging of CPMG-free fast spin echo.

Discussion of Art

Magnetic Resonance Imaging (MRI) is a widely accepted and commercially available technique for obtaining digitized visual images representing the internal structure of objects having substantial populations of atomic nuclei that are susceptible to nuclear magnetic resonance (NMR). In MRI, imposing a strong main magnetic field (B₀) on the nuclei polarizes nuclei in the object to be imaged. The nuclei are excited by a radio frequency (RF) signal at characteristic NMR (Larmor) frequencies. By spatially distributing localized magnetic fields surrounding the object and analyzing the resulting RF responses from the nuclei, a map or image of these nuclei responses as a function of their spatial location is generated and displayed. An image of the nuclei responses provides a non-invasive view of an objects internal structure.

MRI machines, however, are costly to acquire and operate. Therefore, it is desirable to minimize the amount of scanning time required to create an image, while maintaining image quality (e.g. contrast, resolution and signal-to-noise ratio). So-called “fast spin echo” (“FSE”) techniques are commonly used to minimize scan time while creating MRI images of acceptable quality. While there exists a number of FSE techniques, FSE imaging typically uses multiple spin echoes (an ‘echo train’) generated after a single excitation pulse.

Known FSE methods, however, are sensitive to the initial phase of the echo signal. For example, the well-known Carr Purcell Meiboom Gill (CPMG) condition is generally required in order to perform FSE imaging. The CPMG condition is simple to implement: a 90° radio frequency (RF) pulse followed by an echo train induced by successive 180° pulses. To meet the CPMG condition, the initial transverse magnetization must be aligned with the axis of the refocusing pulses.

In connection with the above, FSE is typically acquired assuming the CPMG condition is fulfilled. However, due to the large volume often covered, and the non-linearity of the phase errors, the CPMG condition may not be fulfilled, except for in a restricted volume close to the magnet center. Signal loss and imaging artifacts can therefore result.

Existing imaging methods have sought to eliminate FSE artifacts cause by CPMG violation by utilizing two excitations, CPMG and CP, from which an even and odd echo are separated, a phase correction carried out, and then the even and off echo are added. This method has proven useful with 3DFSE which is most vulnerable to such artifacts. A drawback of this method, however, is the need to run two excitations, which doubles scan time.

In view of the above, it would be particularly beneficial to provide a fast spin echo method that does not require the CPMG condition, and which provides for stable reconstruction and high accelerations so that imaging time penalty can be overcome. In particular, what is needed is a method capable of generating artifact-free images in a significantly reduced scan time.

### BRIEF DESCRIPTION

In an embodiment, a 3D parallel imaging method is provided. The method includes the steps of acquiring a partial CPMG data set, acquiring a partial CP data set, and interleaving the partial CPMG data set and the partial CP data set at different ky-kz locations.

In another embodiment, a magnetic resonance imaging system for 3D parallel imaging is provided. The system includes a primary magnet configured to provide a magnetic field throughout a target volume, at least one gradient magnet configured to provide controllable magnetic field gradients, at least one radio-frequency source of RF emission configured to provide controllable RF pulses, and a control unit configured to control the source of RF emission and to acquire a partial CPMG data set and a partial CP data set in response to the RF pulses. The control unit is also configured to interleave the partial CPMG data set and the partial CP data set at different ky-kz locations

In yet another embodiment, a method for 3D parallel imaging is provided. The method includes the steps of generating a plurality of RF pulses, in response to the RF pulses, under-sampling a first data set, in response to the RF pulses, under-sampling a second data set, and interleaving the first data set with the second data set.

### DRAWINGS

The present invention will be better understood from reading the following description of non-limiting embodiments, with reference to the attached drawings, wherein below:

FIG. 1 depicts schematically an exemplary magnetic resonance imaging (MRI) system that incorporates embodiments of the invention.

FIG. 2 is a diagram illustrating how CPMG+CP acquisition is equivalent to multi-band excitation of two slices.

FIG. 3 is a diagram illustrating noise amplification resulting from non-interleaved and interleaved acquisition, respectively.

FIG. 4 is a diagram illustrating interleaving options of CPMG and CP datasets.

FIG. 5 shows resolution phantoms at the shoulder position for fully sampled CPMG, and CPMG, CP and parallel imaging, respectively.

FIG. 6 shows shoulder images acquired using fully sampled CPMG, and CPMG+CP, respectively.

### DETAILED DESCRIPTION

Reference will be made below in detail to exemplary embodiments of the invention, examples of which are illustrated in the accompanying drawings. Wherever possible, the same reference characters used throughout the drawings refer to the same or like parts, without duplicative description.

As used herein, the terms “substantially,” “generally,” and “about” indicate conditions within reasonably achievable manufacturing and assembly tolerances, relative to ideal desired conditions suitable for achieving the functional purpose of a component or assembly. As used herein, “electrically coupled, “electrically connected” and “electrical communication” means that the referenced elements are directly or indirectly connected such that an electrical current may flow from one to the other. The connection may include a direct conductive connection (i.e., without an intervening capacitive, inductive or active element), an inductive connection, a capacitive connection, and/or any other suitable electrical connection. Intervening components may be present. As will be appreciated, embodiments of the present invention may be used to analyze animal tissue generally and are not limited to human tissue.

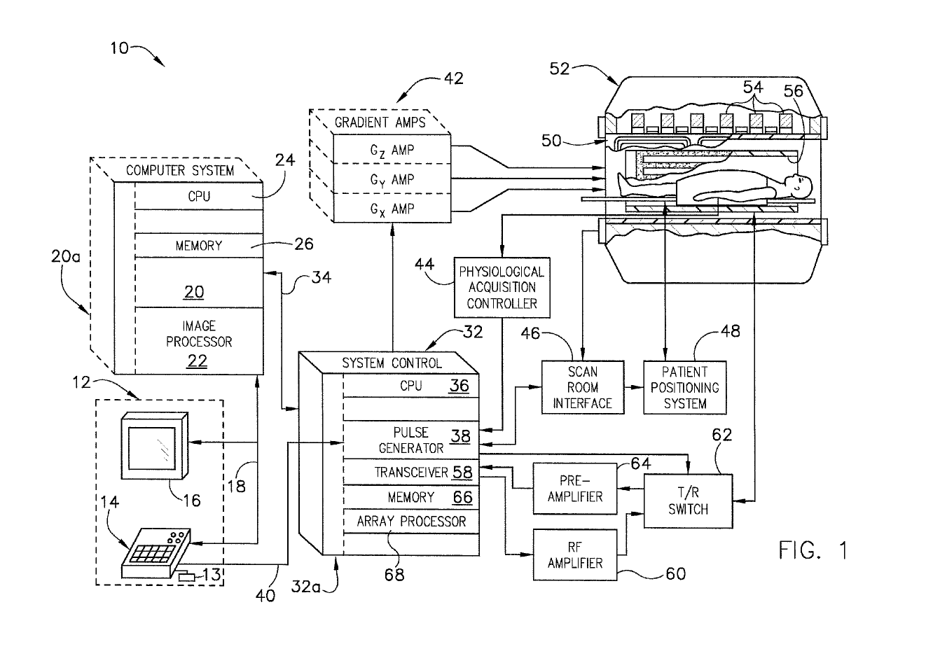

Referring to FIG. 1, the major components of a magnetic resonance imaging (MRI) system 10 incorporating an embodiment of the invention are shown. Operation of the system is controlled from an operator console 12, which includes a keyboard or other input device 13, a control panel 14, and a display screen 16. The console 12 communicates through a link 18 with a separate computer system 20 that enables an operator to control the production and display of images on the display screen 16. The computer system 20 includes a number of modules which communicate with each other through a backplane 20a. These include an image processor module 22, a CPU module 24 and a memory module 26, which may include a frame buffer for storing image data arrays. The computer system 20 communicates with a separate system control 32 through a high-speed serial link 34. The input device 13 can include a mouse, joystick, keyboard, track ball, touch activated screen, light wand, voice control, or any similar or equivalent input device, and may be used for interactive geometry prescription.

The system control 32 includes a set of modules connected together by a backplane 32a. These include a CPU module 36 and a pulse generator module 38 which connects to the operator console 12 through a serial link 40. It is through link 40 that the system control 32 receives commands from the operator to indicate the scan sequence that is to be performed. The pulse generator module 38 operates the system components to carry out the desired scan sequence and produces data which indicates the timing, strength and shape of the RF pulses produced, and the timing and length of the data acquisition window. The pulse generator module 38 connects to a set of gradient amplifiers 42, to indicate the timing and shape of the gradient pulses that are produced during the scan. The pulse generator module 38 can also receive patient data from a physiological acquisition controller 44 that receives signals from a number of different sensors connected to the patient, such as ECG signals from electrodes attached to the patient. And finally, the pulse generator module 38 connects to a scan room interface circuit 46 which receives signals from various sensors associated with the condition of the patient and the magnet system. It is also through the scan room interface circuit 46 that a patient positioning system 48 receives commands to move the patient to the desired position for the scan.

The gradient waveforms produced by the pulse generator module 38 are applied to the gradient amplifier system 42 having Gx, Gy, and Gz amplifiers. Each gradient amplifier excites a corresponding physical gradient coil in a gradient coil assembly generally designated 50 to produce the magnetic field gradients used for spatially encoding acquired signals. The gradient coil assembly 50 forms part of a resonance assembly 52 which includes a polarizing magnet 54 and a whole-body RF coil 56, which is also referred to herein as a “main magnet.” A transceiver module 58 in the system control 32 produces pulses which are amplified by an RF amplifier 60 and coupled to the RF coil 56 by a transmit/receive switch 62.

The resulting signals emitted by the excited nuclei in the patient may be sensed by the same RF coil 56 and coupled through the transmit/receive switch 62 to a preamplifier 64. The amplified MR signals are demodulated, filtered, and digitized in the receiver section of the transceiver 58. The transmit/receive switch 62 is controlled by a signal from the pulse generator module 38 to electrically connect the RF amplifier 60 to the coil 56 during the transmit mode and to connect the preamplifier 64 to the coil 56 during the receive mode. The transmit/receive switch 62 can also enable a separate RF coil (for example, a surface coil) to be used in either the transmit or receive mode.

The MR signals picked up by the RF coil 56 are digitized by the transceiver module 58 and transferred to a memory module 66 in the system control 32. A scan is complete when an array of raw k-space data has been acquired in the memory module 66. This raw k-space data is rearranged into separate k-space data arrays for each image to be reconstructed, and each of these is input to an array processor 68 which operates to Fourier transform the data into an array of image data. This image data is conveyed through the serial link 34 to the computer system 20 where it is stored in memory. In response to commands received from the operator console 12, this image data may be archived in long term storage or it may be further processed by the image processor 22 and conveyed to the operator console 12 and presented on the display 16.

As stated, FSE techniques are commonly used to minimize scan time while creating MRI images of acceptable quality. FSE imaging typically uses multiple spin echoes (an ‘echo train’) generated after a single RF excitation pulse. As will be readily appreciated, FSE data is a linear combination of two pure echoes, even and odd. When CPMG condition is met, both echoes have the same phase. By phase shifting the RF pulses, one of the echoes is shifted by 180 degrees (CP scan). By acquiring CP and CPMG scans, the two echoes can be separated, phase correction applied, and then the echoes combined. However, as indicated above, this requires two excitations and double scan time. Conventional parallel imaging techniques attempting to synthesize CP scan from CPMG is not very effective and is very noisy.

With the present invention, however, it has been discovered that by acquiring partial CPMG and CP data sets and interleaving such partial data sets at different ky-kz locations, a stable reconstruction may be obtained. In particular, it has been discovered that stable reconstruction and high acceleration (and reduced scan time) can be obtained by properly interleaving CP and CPMG data sets in the ky-kz plane. As used herein “partial data set” means a data set that has less than all data points sampled (i.e., some points are un-sampled).

In connection with the above, in an embodiment, a few hundred echo trains with approximately 60-100 echoes in each train may be run utilizing the system 10. Hence, an operator can decide if any given ky, kz point will be acquired in a CP or CPMG train. Similar to multi-slice excitation, the even and odd pure echoes of each FSE train are parallel (CPMG train) or anti-parallel (CP train). Conceptually, each point in the two ky-kz planes of CP and CPMG belong to a third k-space (referred to herein as ks direction) with only two discrete values k1 (even/odd echoes parallel) and k2 (even/odd echoes anti-parallel). This is similar to multi-band excitation, where for N bands, N waveforms are excited in a “slice” discrete k-space. Therefore, conventional GRAPPA parallel imaging can be carried out by fully sampling the center of this 3D k-space and filling the rest of the k-space.

In image domain, the coil sensitivity for both even and odd echoes is the same. As a result, the kernel that connects the even and odd echoes (which is approximately the Fournier Transform of the sensitivity) is very narrow in k-space, so connecting the even/odd echoes is noisy. Interleaving k-space points in all three directions (i.e., ky, kz and ks), however, will result in stable reconstruction

With previous methods, artifacts in FSE due to violation of the CPMG condition can be eliminated by combining two data sets from a CP and a CPMG excitation by separating even and odd echoes. This is particularly useful for 3DFSE, where a large volume is excited. However, as indicated, the need for two excitations doubles scan time, which is already long and prevents clinical use. In response, the present invention provides a 3D parallel imaging method that enables even and odd echo separation with any desirable acceleration, which eliminates FSE artifacts while reducing scan time.

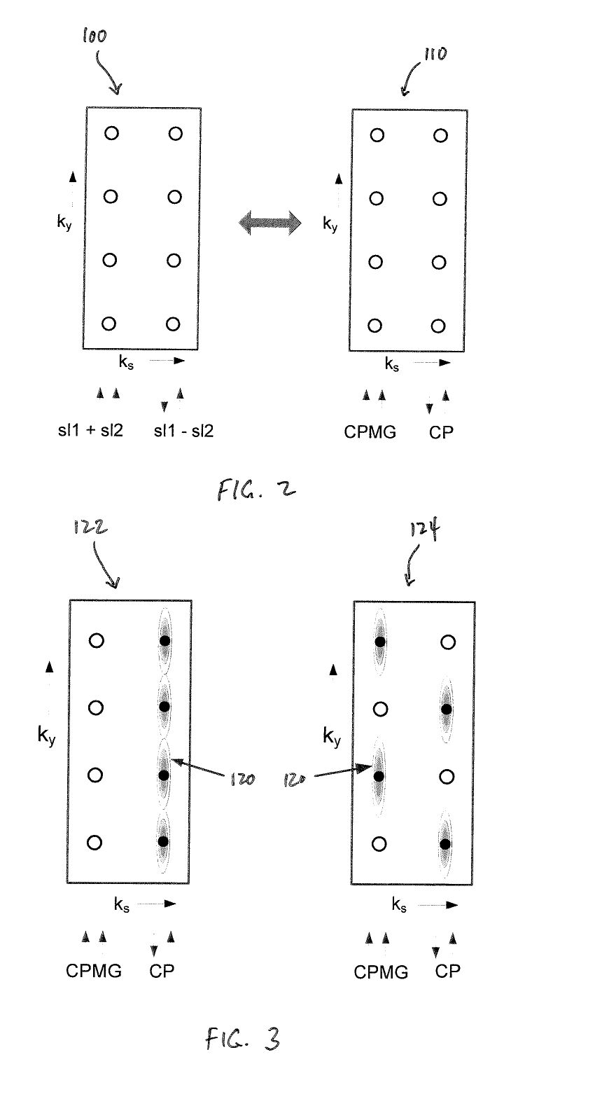

As illustrated in FIG. 2, and as alluded to above, the combination of even and odd echoes using CP/CPMG acquisition is equivalent to the separation of two slices in multi-band excitation. With multi-band excitation, two excitations are performed: in the first excitation, slice 1 (s11) and slice 2 (s12) are excited simultaneously with the same phase. In the second excitation, s12 is phase shifted by it radians from s11. For N slices, N excitations are used with a phase increment of 2π/N in adjacent excitations between adjacent slices. The slices are recovered by Fournier transform along the slice excitation direction, so the slice excitation space is a k-space denoted ks (i.e., k slice), as illustrated by reference numeral 100 in FIG. 2. The full ky-ks plane is acquired and a 2D fast Fournier transform is performed to obtain the N slices. With particular respect to the present invention, CP+CPMG excitation is equivalent to such multi-band excitation with two slices because the even and odd echoes are parallel/anti-parallel in the CPMG/CP excitation, respectively. Data is acquired in 2D k-space ky-ks, denoted by reference numeral 110, shown in FIG. 2.

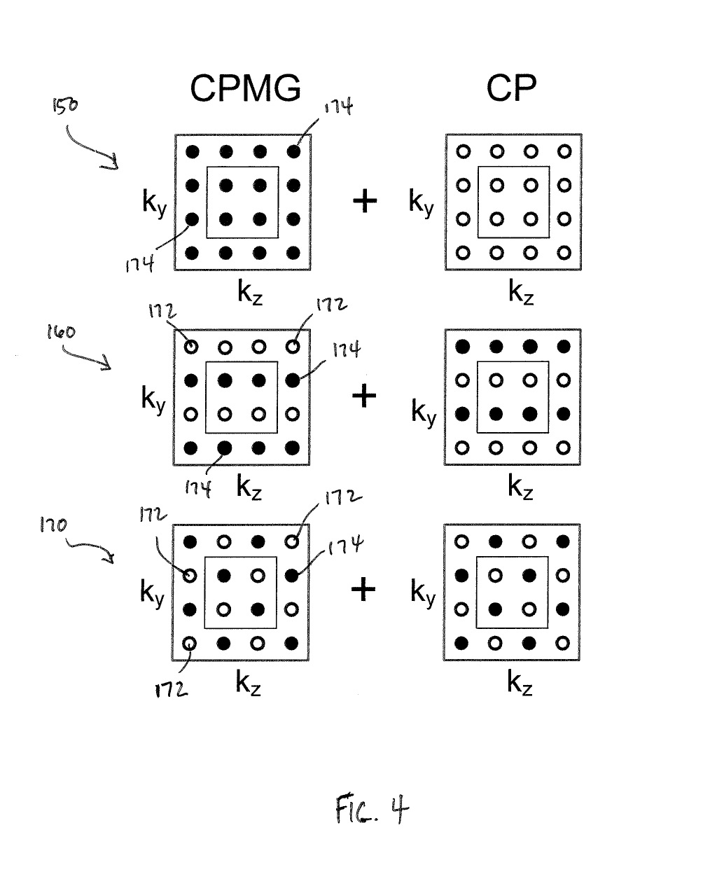

In parallel imaging, a missing k-space point in a coil can be filled by calculating it as a linear combination of the sampled points around it from all the all coils. The values of the linear combination coefficients are referred to as the kernel. In an embodiment, a small number of sampled points are utilized because the coefficient of the kernel centered on a given sampled point decreases rapidly. This coefficient is proportional to the Fournier transform of the spatial sensitivity of the coil. Accordingly, if the spatial sensitivity does not change along the slice direction, the kernel coefficient is much narrower along ks, as shown in FIG. 3. For CP/CPMG, the kernel in ks is even narrower because the even/odd echoes are almost identical. If all the CPMG values are acquired and then attempt to calculate CP with parallel imaging, the value of the kernel 120 from a sampled point at a nearby un-sampled point is small, resulting in noise amplification, as shown in the ky-ks plane 122 shown in FIG. 3. In particular, as illustrated therein, a kernel coefficient around a sampled point is long and thin; for non-interleaved acquisition, kernel coefficients at un-sampled points are low, resulting in noise amplification. However, if the sampled points are interleaved between ky and ks, as shown in the ky-ks plane 124 of FIG. 3, the kernel 120 at the un-sampled locations is higher and noise amplification is avoided. Therefore, interleaving ks and ky improves reconstructed images.

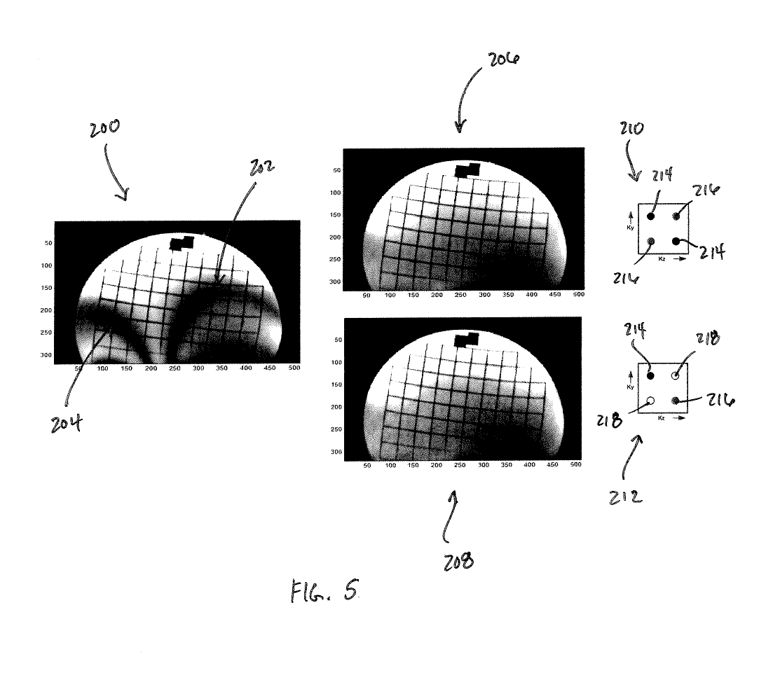

In connection with the above, in 3D FSE, ks is interleaved with ky and kz. FIG. 4 illustrates a few exemplary interleave options 150,160,170, with an acceleration R=2, where the empty circles 172 represent un-sampled points that have to be filled with parallel imaging and the full circles 174 represent sampled points. The first option 150 shown in FIG. 4 illustrates no interleaving, where all the sampled points 174 are CPMG and CP data is calculated with parallel imaging. The second option 160 shown in FIG. 4 illustrates ky interleaving, where alternate ky lines are acquired. The third option 170 shown in FIG. 4 illustrates ky-kz interleaving, where points are acquired on alternate ky and kz grid points. As discussed above, interleaving ks with ky relies on sensitivity variation in y, and interleaving ks with ky-kz relies on y and/or z sensitivity variation. In each case, the periodic cell of the k-space lattice for CP and CPMG is highlighted in FIG. 4.

To compare the parallel imaging reconstructed image quality of the examples discussed above, fully sampled CP and CPMG data sets were acquired and the un-sampled points were set to zero. After reconstruction, the Relative Root Mean Square error (RRMS) was calculated utilizing the equation:

$$RRMS = \sqrt{\frac{Σ {‖ {I}_{full} - {I}_{recon} ‖}^{2}}{Σ {‖ {I}_{full} ‖}^{2}}} \qquad [ 1 ]$$

where I_{full} is the fully sampled image and I_{recon} is the reconstructed parallel imaging image. The sum is over all the voxels. Lower RRMS indicates better parallel imaging reconstruction. The results for different anatomies, number of coils and image matrix are shown in Table 1.

TABLE 1
RRMS for Different Anatomies for CPMG +
CP Excitations with R = 2

| | RRMS no | RRMS y | RRMS y-z | | |
|---|---|---|---|---|---|
| Anatomy | shift | shift | shift | Matrix | coils |
| shoulder | 0.156 | 0.043 | 0.035 | 192 × 192 × 128 | 3 |
| wrist | 0.518 | 0.34 | 0.083 | 256 × 206 × 34 | 8 |
| knee | 0.111 | 0.042 | 0.044 | 256 × 256 × 52 | 8 |
| phantom | 0.199 | 0.040 | 0.045 | 256 × 256 × 142 | 8 |

As illustrated therein, in the case of no k interleaving, the RRMS is high and image quality is low. For ky interleave the RRMS depends on coil geometry. It is high for wrist because coil sensitivity there is almost constant in y. For ky-kz interleave, RRMS is low in all cases. Accordingly, in an embodiment, ky-kz is the preferred under-sampling pattern to be utilized. As used herein “under-sampling” means acquiring less than a full set of data points in k-space for a given pulse sequence.

In connection with the above, in an embodiment, 3D FSE pulse sequence diagram is modified to enable k interleaved CP+CPMG scans with parallel imaging. In particular, the pulse sequence diagram is modified to allow for the acquisition of two echo trains; each CPMG echo train is followed by a CP echo train. At the end of the scan, the reconstructed CPMG and CP images are displayed. CPMG and CP data may be stored as echo 1 and 2, respectively. It is also desirable to ensure that ky and kz values for consecutive CPMG and CP echo trains are as close as possible to minimize eddy current effects.

Based on the user prescription and parallel imaging acceleration factor, the periodic cells of the CP and CPMG scans are determined. Then the k space points (including the fully sampled 30×30 points at the center) acquired by CP and CPMG trains are calculated. Finally each sampled k space point is assigned to a specific CP and/or CPMG echo in a specific echo train. Since in each periodic block there are equal CP and CPMG k space points, the number of echoes within a train and the number of echo trains with CP acquisition is equal to the number of echoes and trains with CPMG acquisition. To eliminate artifacts from eddy current, neighboring k space values of CP and CPMG datasets are acquired at the same echo number in consecutive echo trains. In an embodiment, missing data points may be filled in utilizing an iterative GRAPPA algorithm. After fast Fournier transform in kx, ky, kz and ks, the CPMG and CP images are phase corrected and combined.

In connection with the above, an analysis of a multi-echo sequence with N refocusing pulses P₁ to P_{N} and excitation pulse P₀ shows that the magnetization immediately after each refocusing pulse in the train is a discrete sum of magnetizations components. Let Φ be the phase accrual between adjacent refocusing RF pulses and Φ₀ the phase accrual between P₀ and P₁. Since Φ is the same for all refocusing pulses and Φ₀≠Φ, two distinct echo groups are created in each sampling window. Let the phase of all refocusing pulses be φ and the phase of the excitation pulse P₀ be φ₀. Analysis shows that the phase φ₁ of echo group 1, denoted “even echoes”, and the phase φ₂ of echo group 2, denoted “odd echoes”, is given by:

φ₁=φ₀ even echoes [2a]

φ₂=−φ₀+2φ odd echoes [2b]

φ₁ and φ₂ are the same in all N sampling windows in the train. The phase φ₀ in Equation [2] is the phase immediately prior to P₁ and is given by:

$${ϕ}_{0} = {φ}_{0} + \frac{π}{2} + {ϕ}_{eddy} \qquad [ 3 ]$$

where φ₀ is the phase of P₀ and φ_{eddy} is caused by eddy currents and other imperfections that accumulate between P₀ and P₁. Under ideal conditions φ_{eddy}=0 and φ₁=φ₂ so the even end the odd echoes add coherently, and the signal is strong and varies smoothly in time. This is CPMG. If φ₁ and φ₂ are anti-phase, the even and the odd echo cancel out and the signal is low. This is CP. From Equations [2] and [3] and the definition of CPMG (φ₁=φ₂) and CP (φ₁=φ₂+π)

$$\begin{matrix}\begin{matrix}{φ}_{0} = φ + ( n - \frac{1}{2} ) \cdot π & n = 0 , \pm 1 , \pm 2 , … . for CPMG\end{matrix} & [ 4 ] \\ \begin{matrix}{φ}_{0} = φ + n \cdot π & n = 0 , \pm 1 , \pm 2 , … . for CP\end{matrix} & [ 5 ]\end{matrix}$$

In standard FSE both echoes are sampled in the same window with φ=0 and φ₀ is given by [4] with n=0 (CPMG). In this case the signal is

S=Sₑᵥₑₙ exp(i·φ_{eddy})+S_{odd} exp(−i·φ_{eddy})≈2·Sₑᵥₑₙ cos(φ_{eddy}) [6]

where Sₑᵥₑₙ and S_{odd} are the even/odd echoes amplitudes. Equation [6] shows that if φ_{eddy}≠0 there is a signal loss. If φ_{eddy} has a linear gradient term, there is also ghosting and blurring. In summary, to fulfill the CPMG condition φ₀ and φ must fulfill Equation [4] and φ_{eddy} must be zero in all the imaging volume. In practice it is impossible to null φ_{eddy} everywhere, so artifacts are unavoidable. As discussed above, 3D FSE is vulnerable to artifacts because the volume of interest is large.

To solve this problem, one can separate even and odd echoes, phase-correct them on a pixel-by-pixel basis and add them coherently. Since there are two echoes (even and odd), this must be done with two excitations and phase cycling of φ₀ and/or φ, such that in the second excitation the odd echo inverts its sign. As explained above, in CPMG the even and odd echoes are in phase, while in CP the odd echo becomes anti-phase. Hence phase cycling with CPMG in the first excitation and CP in the second can be used to separate the echoes. For CMPG Equation 4 must be fulfilled. The simplest option is φ=0 and φ₀ with n=0 in [4]. From Equations [2], [3] and [6]:

S_{CPMG}=Sₑᵥₑₙ exp(iφ_{eddy})+S_{odd} exp(−iφ_{eddy}) [7a]

For CP, Equation 5 must be fulfilled. Assuming φ=0 and n=0 in Equation [5] and using [2] and [3]:

$${S}_{CP} = {S}_{even} exp [ i ( {ϕ}_{eddy} + \frac{π}{2} ) ] + {S}_{odd} exp [ - i ( {ϕ}_{eddy} + \frac{π}{2} ) ] = i {S}_{even} exp ( {iϕ}_{eddy} ) - i {S}_{odd} exp ( - {iϕ}_{eddy} ) \qquad [ 7 b ]$$

To simplify the mathematics, S_{CP1} can be defined as:

S_{CP1}≡−iS_{CP}=Sₑᵥₑₙ exp(iφ_{eddy})−S_{odd} exp(−iφ_{eddy}) [7c]

### From Equation [7]:

$$\begin{matrix}{S}_{1} ≡ {S}_{even} exp ( {iϕ}_{eddy} ) = \frac{{S}_{CPMG} + {S}_{CP 1}}{2} & [ 8 a ] \\ {S}_{2} ≡ {S}_{odd} exp ( - {iϕ}_{eddy} ) = \frac{{S}_{CPMG} + {S}_{CP 1}}{2} & [ 8 b ]\end{matrix}$$

As will be readily appreciated, many other phase cycling combinations are possible by selecting other values of φ and n in [4] and [5], without departing from the broader aspects of the present invention, but from signal-to-noise considerations CPMG and CP excitations must always be used. The phase difference between S₁ and S₂ is 2φ_{eddy} and it can be used it to determine φ_{eddy} in space:

angle(S₁, S₂)=2φ_{eddy} [9]

Rather than phase correct and add S₁ and S₂ in [8a] and [8b], however, a simpler but equivalent operation is to add their magnitudes:

S=|S₁|+|S₂| [10]

It has been shown that to retain maximum FSE image sharpness it is advantageous to phase-correct S₂ with respect to S₁ with a low resolution smoothed version of 2φ_{eddy}:

S=S₁+exp(iψ)·S₂ [11]

where ψ is a smoothed version of 2φ_{eddy}.

In view of the above, a stable reconstruction of an artifact free image from the even and odd echoes can thus be obtained from a single scan.

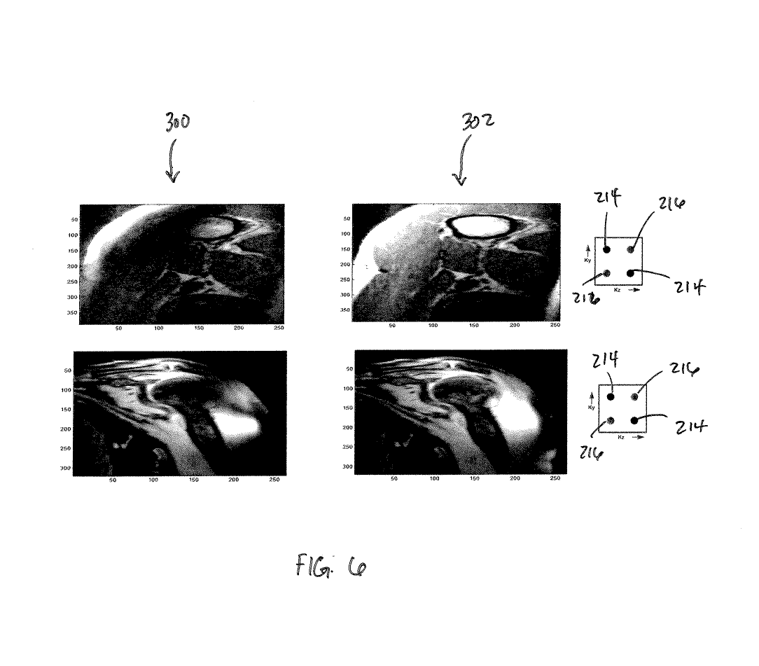

FIG. 5 shows a resolution phantom located at the shoulder position with a 206×256×192 matrix along the readout, y and z using 8-channel coil. The image 200 is a fully sampled CPMG image with significant artifacts 202,204 due to violation of the CPMG condition. The images 206,208 were acquired with CPMG+CP excitations with parallel imaging. The sampling patterns for images 206 and 208 are indicated at 210 and 212, respectively, where full dot 214 is a CPMG sampled point, full dot 216 is a CP sampled point, and the empty dot 218 is a point un-sampled by either CPMG and CP. For the first image 206 the acceleration R=2 and for the second image 208 the acceleration R=4. As shown, the CPMG+CP+parallel imaging images 206, 208 artifact free, and the scan time for image 208 is half that of the image 200.

FIG. 6 shows shoulder images acquired with a 3-channel coil. Images 300 are fully sampled CPMG images while images 302 are CPMG+CP images with acceleration R=2. As shown, the images 302 are artifact free. The ability of CPMG+CP interleaved parallel imagining to generate images with very large acceleration factors was also tested. Through testing, it has been demonstrated that a much accelerated CPMG+CP acquisition, where R=9, results in the removal of FSE artifacts and good image quality.

As discussed above, by interleaving ks with ky and kz, good parallel imaging with small noise amplification, even at high acceleration factor, can be realized. The method of the present invention has been show to significantly reduce the presence of conventional FSE artifacts, especially at off-center slices, while keeping scan time and signal to noise ratio comparable to that of conventional FSE. Another advantage is the possibility to replace the excitation RF pulse with a prep sequence that can be used to improve fat signal suppression and allow image contrast manipulations.

Indeed, the system and method of the present invention can be utilized to obtain clear images with minimal artifacts, even when imaging at far off isocenter (e.g., a shoulder), as compared to existing methods. Moreover, the parallel imaging reconstruction approach of the present invention combined with the interleaved acquisition of CPMG and CP data achieves a scan time of one acquisition with low g factor. In vivo-shoulder scans illustrate that the inventive method described herein produces artifact free images, where CPMG data alone is not suitable. The system and method of the present invention therefore enables CPMG free FSE acquisition without scan time penalty.

In an embodiment, a 3D parallel imaging method is provided. The method includes the steps of acquiring a partial CPMG data set, acquiring a partial CP data set, and interleaving the partial CPMG data set and the partial CP data set at different ky-kz locations. The method may also include the step of generating a plurality of RF pulses, wherein the partial CP data set and the partial CPMG data set are acquired in response to the generation of RF pulses. In an embodiment, the plurality of RF pulses may define two echo trains, a CPMG echo train followed by a CP echo train. In an embodiment, the partial CPMG data set includes a first plurality of sampled k-space points and the partial CP data set includes a second plurality of sampled k-space points, where the second plurality of sampled k-space points are different from the first plurality of sampled k-space points. In an embodiment, the CPMG data set includes a first plurality of un-sampled k-space points, the CP data set includes a second plurality of un-sampled k-space points, the first plurality of sampled k-space points correspond to the second plurality of un-sampled k-space points, and the second plurality of sampled k-space points correspond to the first plurality of un-sampled k-space points. In an embodiment, the k-space points include ky points and kz points. In an embodiment, the first plurality of sampled k-space points are in alternate ky lines. In an embodiment, the first plurality of sampled k-space points are alternate ky and kz grid points. However, any other combination of acquired CP and/or CPMG k space points is possible. The exact sampling pattern depends on parallel imaging accelerations and the acquired data matrix in ky-kz plane. In an embodiment, the method may also include the steps of storing the partial CPMG data set and storing the partial CP data set. In an embodiment, the method may also include arranging the CPMG data set and the CP data set into equal echo trains of CPMG and CP excitations. In an embodiment, the method includes filling in missing data points with parallel imaging. Filling in the missing data points with parallel imaging may include utilizing an iterative GRAPPA algorithm. In an embodiment, the method may include the steps of performing fast Fournier transform in kx, ky, kz and ks. The two data sets along the slice dimension are the images of the even and the odd echoes.

In an embodiment a magnetic resonance imaging system for 3D parallel imaging is provided. The system includes a primary magnet configured to provide a magnetic field throughout a target volume, at least one gradient magnet configured to provide controllable magnetic field gradients, at least one radio-frequency source of RF emission configured to provide controllable RF pulses, and a control unit configured to control the source of RF emission and to acquire a partial CPMG data set and a partial CP data set in response to the RF pulses. The control unit is also configured to interleave the partial CPMG data set and the partial CP data set at different ky-kz locations. In an embodiment, the RF pulses define two echo trains, a CPMG echo train followed by a CP echo train, wherein the partial CPMG data set is acquired in response to the CPMG echo train and the partial CP data set is acquired in response to the CP echo train. In an embodiment, the CPMG data set includes a first plurality of sampled k-space points and the CP data set includes a second plurality of sampled k-space points. The second plurality of sampled k-space points are different from the first plurality of sampled k-space points. In an embodiment, the first plurality of sampled k-space points are in alternate ky lines. In an embodiment, the first plurality of sampled k-space points are alternate ky and kz grid points. In an embodiment, the control unit is configured to fill in missing data points utilizing parallel imaging. In an embodiment, the control unit is configured to perform a 3D fast Fournier transform, phase correct CPMG and CP images and combine the phase corrected CPMG and CP images. In an embodiment, the system also includes an operator console electrically connected to the control unit and configured to allow a user to configure the magnetic resonance imaging system for CPMG+CP acquisition.

In yet another embodiment, a method for 3D parallel imaging is provided. The method includes the steps of generating a plurality of RF pulses, in response to the RF pulses, under-sampling a first data set, in response to the RF pulses, under-sampling a second data set, and interleaving the first data set with the second data set.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope.

While the dimensions and types of materials described herein are intended to define the parameters of the invention, they are by no means limiting and are exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, terms such as “first,” “second,” “third,” “upper,” “lower,” “bottom,” “top,” etc. are used merely as labels, and are not intended to impose numerical or positional requirements on their objects. Further, the limitations of the following claims are not written in means-plus-function format and are not intended to be interpreted based on 35 U.S.C. §122, sixth paragraph, unless and until such claim limitations expressly use the phrase “means for” followed by a statement of function void of further structure.

This written description uses examples to disclose several embodiments of the invention, including the best mode, and also to enable one of ordinary skill in the art to practice the embodiments of invention, including making and using any devices or systems and performing any incorporated methods. The patentable scope of the invention is defined by the claims, and may include other examples that occur to one of ordinary skill in the art. Such other examples are intended to be within the scope of the claims if they have structural elements that do not differ from the literal language of the claims, or if they include equivalent structural elements with insubstantial differences from the literal languages of the claims.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

Since certain changes may be made in the above-described invention, without departing from the spirit and scope of the invention herein involved, it is intended that all of the subject matter of the above description or shown in the accompanying drawings shall be interpreted merely as examples illustrating the inventive concept herein and shall not be construed as limiting the invention.

What is claimed is:

1. A 3D parallel imaging method, comprising the steps of:
acquiring a partial CPMG data set;
acquiring a partial CP data set; and
interleaving the partial CPMG data set and the partial CP data set at different ky-kz locations.

2. The method according to claim 1, further comprising the step of:
generating a plurality of RF pulses;
wherein the partial CP data set and the partial CPMG data set are acquired in response to the generation of RF pulses.

3. The method according to claim 2, wherein:
the plurality of RF pulses define two echo trains, a CPMG echo train followed by a CP echo train.

4. The method according to claim 3, wherein:
the partial CPMG data set includes a first plurality of sampled k-space points; and
the partial CP data set includes a second plurality of sampled k-space points, the second plurality of sampled k-space points being different from the first plurality of sampled k-space points.

5. The method according to claim 4, wherein:
the CPMG data set includes a first plurality of un-sampled k-space points;
the CP data set includes a second plurality of un-sampled k-space points;
the first plurality of sampled k-space points correspond to the second plurality of un-sampled k-space points; and
the second plurality of sampled k-space points correspond to the first plurality of un-sampled k-space points.

6. The method according to claim 5, wherein:
the k-space points include ky points and kz points.

7. The method according to claim 4, wherein:
the first plurality of sampled k-space points are in alternate ky lines.

8. The method according to claim 4, wherein:
the first plurality of sampled k-space points are alternate ky and kz grid points.

9. The method according to claim 1, further comprising the steps of:
storing the partial CPMG data set; and
storing the partial CP data set.

10. The method according to claim 1, further comprising the step of:
arranging the CPMG data set and the CP data set into equal echo trains of CPMG and CP excitations.

11. The method according to claim 10, further comprising the step of:
filling in missing data points with parallel imaging.

12. The method according to claim 11, wherein:
filling in the missing data points with parallel imaging includes utilizing an iterative GRAPPA algorithm.

13. The method according to claim 12, further comprising the steps of:
performing a 3D fast Fournier transform;
phase correcting CPMG and CP images; and
combining the phase corrected CPMG and CP images.

14. A magnetic resonance imaging system for 3D parallel imaging, comprising:
a primary magnet configured to provide a magnetic field throughout a target volume;
at least one gradient magnet configured to provide controllable magnetic field gradients;
at least one radio-frequency source of RF emission configured to provide controllable RF pulses; and
a control unit configured to control the source of RF emission and to acquire a partial CPMG data set and a partial CP data set in response to the RF pulses;
wherein the control unit is further configured to interleave the partial CPMG data set and the partial CP data set at different ky-kz locations.

15. The magnetic resonance imaging system of claim 14, wherein:
the RF pulses define two echo trains, a CPMG echo train followed by a CP echo train;
wherein the partial CPMG data set is acquired in response to the CPMG echo train and the partial CP data set is acquired in response to the CP echo train.

16. The magnetic resonance imaging system of claim 15, wherein:
the CPMG data set includes a first plurality of sampled k-space points; and
the CP data set includes a second plurality of sampled k-space points, the second plurality of sampled k-space points being different from the first plurality of sampled k-space points.

17. The magnetic resonance imaging system of claim 16, wherein:
the first plurality of sampled k-space points are in alternate ky lines.

18. The magnetic resonance imaging system of claim 16, wherein:
the first plurality of sampled k-space points are alternate ky and kz grid points.

19. The magnetic resonance imaging system of claim 15, wherein:
the control unit is configured to fill in missing data points utilizing parallel imaging.

20. The magnetic resonance imaging system of claim 15, wherein:
the control unit is configured to perform a 3D fast Fournier transform, phase correct CPMG and CP images and combine the phase corrected CPMG and CP images.

21. The magnetic resonance imaging system of claim 15, further comprising:
an operator console electrically connected to the control unit and configured to allow a user to configured the magnetic resonance imaging system for CPMG+CP acquisition.

22. A method for 3D parallel imaging, comprising the steps of:
generating a plurality of RF pulses;
in response to the RF pulses, under-sampling a first data set;
in response to the RF pulses, under-sampling a second data set; and
interleaving the first data set with the second data set.
